(19) United States
(12) Patent Application Publication
(10) Pub. No.: US 2020/0335645 A1
(43) Pub. Date: Oct. 22, 2020

(54) ELECTROCONDUCTIVE PASTE FOR SOLAR CELL ELECTRODE, AND SOLAR CELL MANUFACTURED USING SAME

(71) Applicant: LS-NIKKO COPPER INC., Ulsan (KR)

(72) Inventors: In Chul KIM, Yongin (KR); Hwa Joong KIM, Seoul (KR); Tae Hyun JUN, Seongnam (KR); Min Soo KO, Seoul (KR); Mun Seok JANG, Seoul (KR); Hwa Young NOH, Seongnam (KR); Chung Ho KIM, Namyangju (KR); Kang Ju PARK, Seongnam (KR)

(73) Assignees: LS-NIKKO COPPER INC., Ulsan (KR); LS-NIKKO COPPER INC., Ulsan (KR)

(21) Appl. No.: 16/761,737

(22) PCT Filed: Oct. 18, 2018
(86) PCT No.: PCT/KR2018/012331

§ 371 Date: May 5, 2020

(30) Foreign Application Priority Data
Nov. 6, 2017 (KR) 10-2017-0146993

(51) Int. Cl. H01L 31/0224

(52) U.S. Cl. CPC H01L 31/022425

(57) ABSTRACT

The present invention provides an electroconductive paste for a solar cell electrode, comprising a metal powder, glass frit, a metal oxide, an organic binder, and a solvent, wherein the metal oxide comprises an oxide of at least one kind of metal selected from a group consisting of tungsten (W), antimony (Sb), nickel (Ni), copper (Cu), magnesium (Mg), calcium (Ca), ruthenium (Ru), molybdenum (Mo), and bismuth (Bi).

### TECHNICAL FIELD

The present invention relates to an electroconductive paste used for forming an electrode of a solar cell, and a solar cell manufactured using the same.

### BACKGROUND ART

A solar cell is a semiconductor device that converts solar energy into electrical energy, and generally has a p-n junction type. The basic structure of the solar cell is the same as that of a diode. FIG. 1 illustrates a structure of a general solar cell device. The solar cell device is generally constructed using a p-type silicon semiconductor substrate 10 having a thickness of 180 to 250 μm. An n-type impurity layer 20 having a thickness of 0.3 to 0.6 μm is formed on a light-receiving surface side of the silicon semiconductor substrate, and an anti-reflection film 30 and a front electrode 100 are formed thereon. Further, a back aluminum electrode 50 is formed on a back surface of the p-type silicon semiconductor substrate. The front electrode 100 is formed in such a manner that an electroconductive paste formed by mixing silver-based conductive particles (silver powder), a glass fit, an organic vehicle, and additives is applied on the anti-reflection film 30, followed by firing. The back aluminum electrode 50 is formed in such a manner that an aluminum paste composition composed of an aluminum powder, a glass frit, an organic vehicle, and additives is applied by screen printing or the like, followed by drying, and then firing at a temperature of equal to or greater than 660° C. (melting point of aluminum). During firing, aluminum diffuses into the p-type silicon semiconductor substrate, thereby forming an Al—Si alloy layer between the back electrode and the p-type silicon semiconductor substrate, and at the same time, a p+layer 40 is formed as an impurity layer by diffusion of aluminum atoms. The presence of such a p+layer prevents recombination of electrons and obtains a back surface field (BSF) effect that improves collection efficiency of generated carriers. A back silver electrode 60 may be further positioned under the back aluminum electrode 50.

Because a unit solar cell including a solar cell electrode as above has a low electromotive force, a photovoltaic module formed by connecting a plurality of unit solar cell cells to have an appropriate electromotive force is used. Here, respective unit solar cells are connected to each other by conductor ribbons of a predetermined length coated with lead. In this case, a so-called leaching phenomenon in which Ag, a component of electrodes, is dissolved by Sn, which is a component of the ribbons, may occur. In an effort to solve this problem, the amount and ratio of Ag and glass frit of an electroconductive paste may be adjusted to implement desired electrical characteristics and adhesion. In this case, however, in order to achieve high efficiency, the number of patterns of a busbar electrode constituting a front electrode may increase while the width of the patterns becomes narrower, leading to a problem of a decrease in adhesion between a ribbon and the front electrode.

### DISCLOSURE

### Technical Problem

An objective of the present invention is to provide an electroconductive paste composition for a solar cell electrode, the electroconductive paste composition being capable of reducing a leaching phenomenon in which a component of an electrode is dissolved in the process of soldering of a ribbon and an electrode, in order to enhance electrical characteristics of a front electrode.

However, the objectives of the present invention are not limited to the above-mentioned objective, and other objectives not mentioned will be clearly understood by those skilled in the art from the following description.

### Technical Solution

In order to accomplish the above objective, the present invention provides an electroconductive paste for a solar cell electrode, the electroconductive paste including: a metal powder; a glass frit; a metal oxide; an organic binder; and a solvent, wherein the metal oxide may include at least one of a first metal oxide including tungsten and a second metal oxide including antimony.

Further, the metal oxide may include the first metal oxide and the second metal oxide, wherein the first metal oxide may be WO₃ and the second metal oxide may be Sb₂O₃.

Further, a weight ratio of the first metal oxide to the second metal oxide may be 1:1 to 5.

Further, with respect to the total weight of the electroconductive paste, the amount of the first metal oxide may be 0.1 to 0.3 wt %, and the amount of the second metal oxide may be 0.1 to 0.4 wt %.

Further, with respect to the total weight of the electroconductive paste, the amount of the first metal oxide may be 0.1 wt % and the amount of the second metal oxide may be 0.4 wt %.

Further, with respect to the total weight of the electroconductive paste, the amount of the glass frit may be 2.5 to 3.1 wt %.

The present invention further provides a solar cell, including: a front electrode on a substrate; and a back electrode under the substrate, wherein the front electrode may be produced by applying any one of the above-mentioned electroconductive pastes, followed by drying and firing.

### Advantageous Effects

In the present invention, by adding WO₃ and Sb₂O₃ to an electroconductive paste for a solar cell electrode, it is possible to increase adhesion between a ribbon and a front electrode, thereby reducing a leaching phenomenon that occurs in the process of soldering the ribbon to the front electrode. Further, even when NiO, CuO, and Bi₂O₃ are added to the electroconductive paste for the solar cell electrode, it is possible to reduce the leaching to phenomenon.

### DESCRIPTION OF DRAWINGS

FIG. 1 is a schematic sectional view illustrating a general solar cell device.

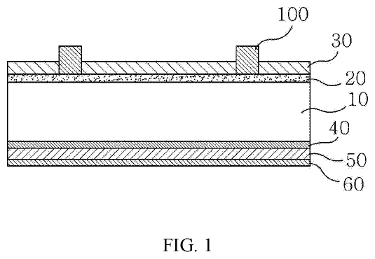

### MODE FOR INVENTION

Prior to describing the present invention in detail below, it should be understood that the terms used herein are merely intended to describe specific embodiments and are not to be construed as limiting the scope of the present invention, which is defined by the appended claims. Unless otherwise defined, all terms including technical and scientific terms used herein have the same meaning as commonly understood by one of ordinary skill in the art to which this invention belongs.

Throughout this specification and the claims, unless otherwise defined, the terms “comprise”, “comprises”, and “comprising” will be understood to imply the inclusion of a stated object, a step or groups of objects, and steps, but not the exclusion of any other objects, steps or groups of objects or steps.

Meanwhile, unless otherwise noted, various embodiments of the present invention may be combined with any other embodiments. In particular, any feature which is mentioned preferably or favorably may be combined with any other features which may be mentioned preferably or favorably. Hereinafter, a description will be given of embodiments of the present invention and effects thereof with reference to the accompanying drawings.

A paste according to an embodiment of the present invention is a paste suitable for use in forming a solar cell electrode, and an electroconductive paste for a solar cell electrode to reduce leaching occurring upon ribbon attachment is provided. More in detail, the electroconductive paste composition may include a metal powder, a glass frit, a metal oxide, an organic vehicle, and the like. In addition thereto, various additives may be included.

As the metal powder, a silver powder, copper powder, nickel powder, aluminum powder, or the like may be used. The silver powder is mainly used for a front electrode, and the aluminum powder is mainly used for a back electrode. Hereinafter, for convenience of description, the metal powder will be described using the silver powder as an example. The following description can be equally applied to other metal powders.

The amount of the metal powder is 70 to 95 wt %, more preferably 85 to 95 wt %, with respect to the total weight (wt) of the electroconductive paste composition, considering electrode thickness formed during printing and linear resistance of the electrode.

The silver powder is preferably a pure silver powder, and in addition, a silver-coated composite powder in which a silver layer is formed on at least the surface thereof, or an alloy including silver as a main component may be used. Further, other metal powders may be mixed and used. Examples may include aluminum, gold, palladium, copper, and nickel.

The silver powder may have an average particle diameter of 0.05 to 3 μm, and preferably 0.5 to 2.5 μm when considering ease of pasting and density during firing, and the shape thereof may be at least one of spherical, needle-like, plate-like, and amorphous. The silver powder may be used by mixing two or more powders having different average particle diameters, particle size distributions, and shapes.

The composition, particle diameter, and shape of the glass frit are not particularly limited. A leaded glass frit as well as a lead-free glass frit may be used. Preferably, as the components and amounts of the glass frit, on an oxide basis, 5 to 29 mol % of PbO, 20 to 34 mol % of TeO₂, 3 to 20 mol % of Bi₂O₃, equal to or less than 20 mol % of SiO₂, and equal to or less than 10 mol % of B₂O₃ are included, and an alkali metal (Li, Na, K, and the like) and an alkaline earth metal (Ca, Mg, and the like) are included in an amount of 10 to 20 mol %. By organically combining the amount of each component, it is possible to prevent an increase in the line width of an electrode, ensuring excellent contact resistance at high sheet resistance, and ensuring excellent short-circuit current characteristics.

The average particle diameter of the glass frit is not limited, but may fall within the range of 0.05 to 4 Ian, and the glass frit may be used by mixing different types of particles having different average particle diameters. Preferably, at least one type of glass frit has an average particle diameter D50 of equal to or greater than 0.1 μm and equal to or less than 3 μm. This makes it possible to ensure excellent reactivity during firing, and in particular, minimize damage to an n-layer at a high temperature, improve adhesion, and ensure excellent open-circuit voltage (Voc). It is also possible to reduce an increase in the line width of an electrode during firing.

The transition temperature of the glass frit may be 200 to 500° C., preferably 250 to 450° C., and when this range is satisfied, an effect of desired physical properties can be more efficiently achieved.

The amount of the glass frit is 0.1 to 15 wt % with respect to the total weight of the electroconductive paste composition, and more preferably 0.5 to 4 wt %.

The metal oxide includes an oxide of at least any one of metals selected from the group consisting of tungsten (W), antimony (Sb), nickel (Ni), copper (Cu), magnesium (Mg), calcium (Ca), ruthenium (Ru), molybdenum (Mo), and bismuth (Bi). The average particle diameter of the metal oxide may be 0.01 to 5 μm, and considering an effect thereof, preferably 0.02 to 2 Ian.

When the metal oxide includes at least one of oxides of the metals, an oxide of antimony (Sb) preferably must be included. When the oxide of antimony is included, the amount of the metal oxide with respect to the total weight of the electroconductive paste is preferably 0.1 to 0.5 wt %, more preferably 0.2 to 0.4 wt %.

The metal oxide preferably includes a first metal oxide and a second metal oxide of at least any two of metals selected from the group consisting of tungsten (W), antimony (Sb), nickel (Ni), copper (Cu), magnesium (Mg), calcium (Ca), ruthenium (Ru), molybdenum (Mo), and bismuth (Bi).

When the metal oxide includes at least two of oxides of the metals, an oxide of tungsten (W) preferably must be included as the first metal oxide, and an oxide of antimony (Sb) must be included as the second metal oxide. In this case, the weight ratio of the first metal oxide to the second metal oxide is preferably 1:1 to 5. Further, when the oxide of tungsten and the oxide of antimony are included, the amount of the first metal oxide is preferably 0.1 to 0.3 wt % and the amount of the second metal oxide is preferably 0.1 to 0.5 wt % with respect to the total weight of the electroconductive paste, and more preferably, the amount of the first metal oxide is 0.1 to 0.3 wt %, and the amount of the second metal oxide is 0.2 to 0.4 wt %.

The organic vehicle is not limited, but may include an organic binder, a solvent, and the like. The use of the solvent may be omitted in some cases. The organic vehicle is not limited, but may be included in an amount of 3 to 25 wt % with respect to the total weight of the electroconductive paste composition, and preferably 5 to 15 wt %.

The organic vehicle is required to have characteristics such as maintaining a uniform mixture of the metal powder, the glass frit, and the like. For example, when the electroconductive paste is applied to a substrate by screen printing, there is a need for characteristics that make the conductive paste homogeneous to suppress blurring and flow of a printed pattern, and also improve dischargeability and plate separation characteristics of the conductive paste from a screen plate.

The organic binder included in the organic vehicle is not limited, but examples thereof may include a cellulose ester compound such as cellulose acetate, cellulose acetate butyrate, and the like; a cellulose ether compound such as ethyl cellulose, methyl cellulose, hydroxy propyl cellulose, hydroxy ethyl cellulose, hydroxy propyl methyl cellulose, hydroxy ethyl methyl cellulose, and the like; an acrylic compound such as polyacrylamide, polymethacrylate, polymethyl methacrylate, polyethyl methacrylate, and the like; and a vinyl compound such as polyvinyl butyral, polyvinyl acetate, polyvinyl alcohol, and the like. At least one of the organic binders may be selected and used.

As a solvent used for dilution of the composition, at least one of compounds selected from the group consisting of alpha-terpineol, texanol, dioctyl phthalate, dibutyl phthalate, cyclohexane, hexane, toluene, benzyl alcohol, dioxane, diethylene glycol, ethylene glycol monobutyl ether, ethylene glycol monobutyl ether acetate, diethylene glycol mono butyl ether, diethylene glycol mono butyl ether acetate, and the like is preferably used.

As an additive, a dispersant, a thickener, a thixotropic agent, a leveling agent, or the like may be selectively used. Examples of the dispersant may include BYK-110, 111, 108, 180, and the like, examples of the thickener may include BYK-410, 411, 420, and the like, examples of the thixotropic agent include BYK-203, 204, 205, and the like, and examples of the leveling agent include BYK-308, 378, 3440, and the like, but the present invention is not limited thereto.

In the present invention, by adjusting the amount of the above-mentioned glass frit, it is possible to reduce the phenomenon of leaching occurring when soldering a ribbon to an electrode.

Further, in the present invention, by adjusting the amount of the above-mentioned metal oxide, it is possible to reduce the phenomenon of leaching occurring when soldering a ribbon to an electrode.

More in detail, in the present invention, by selecting at least one or two of WO₃, Sb₂O₃, NiO, CuO, MgO, CaO, RuO, MoO, and Bi₂O₃ and adjusting the amount ratio of the selected metal oxides, it is possible to reduce the phenomenon of leaching occurring when soldering a ribbon to an electrode.

However, as described later, when the amount ratio of the metal oxides is excessively increased, open-circuit voltage may decrease or contact resistance may increase.

A description will be given in more detail through the following examples.

### Example 1

A paste composition for a lower printed layer of an electrode is as follows. For a silver powder, particles (produced by LS-Nikko Copper Inc., D50=2.0 μm, and Tap Density=4.8 g/cm³) were used and added in an amount of 89.5 wt % with respect to the total paste composition. For a glass frit, 2.5 wt % of a Pb-based glass frit having a Tg of 280° C. was added with respect to the paste composition. For a resin, 0.5 wt % of STD-10 (produced by DOW) was added. For an additive, 0.5 wt % of THIXATROL MAX (produced by ELEMENTIS) was added to impart thixotropic characteristics. For a dispersant, 1.0 wt % of ED-152 (produced by KUSUMOTO) was added. For a solvent, 1.5 wt % of dibasic ester (DBE, containing dimethyl adipate, dimethyl glutrate, and dimethyl succinate and produced by TCI), and 3.5 wt % of buthyl carbitol acetate (produced by Eastman) were added.

In manufacturing a substrate for a solar cell, a 156 mm×156 mm single-crystal silicon wafer was used. The wafer was doped with phosphorus (P) through a diffusion process using POCl3 at 900° C. in a tube furnace to form a 100 to 500 nm-thick emitter layer having a sheet resistance of 90 Ω/sq. A silicon nitride film was formed on the emitter layer by PECVD to form an 80 nm-thick anti-reflection film. A front electrode was screen-printed on the anti-reflection film. The lower printed layer of the front electrode was formed by screen-printing the prepared paste composition for the lower printed layer using a 34 μm mask having a 15 μm emulsion film on a 360-16 mesh with a printing machine by Baccini. In the same manner, a paste composition for an upper printed layer was screen-printed on the lower printed layer. A back electrode was screen-printed using a product of D company. Thereafter, the wafer was subjected to drying at 300° C. for 30 seconds in a BTU furnace, followed by firing in a firing furnace at 900° C. for 60 seconds to manufacture a substrate for a solar cell. The drying was performed at 300° C. for 30 seconds using BTU equipment, and the firing was performed at 900° C. for 60 seconds using a Despatch furnace.

### Example 2

The procedure in this example was performed in the same manner as described in Example 1, except that 2.7 wt % of the glass frit was added.

### Example 3

The procedure in this example was performed in the same manner as described in Example 1, except that 2.9 wt % of the glass frit was added.

### Example 4

The procedure in this example was performed in the same manner as described in Example 1, except that 3.1 wt % of the glass frit was added.

### Example 5

The procedure in this example was performed in the same manner as described in Example 2, except that 2.7 wt % of the glass frit was added, and 0.1 wt % of WO₃ (0.1 μm) was used.

### Example 6

The procedure in this example was performed in the same manner as described in Example 2, except that 2.7 wt % of the glass frit was added, and 0.2 wt % of WO₃ (0.1 μm) was used.

### Example 7

The procedure in this example was performed in the same manner as described in Example 2, except that 2.7 wt % of the glass frit was added, and 0.3 wt % of WO₃ (0.1 μm) was used.

### Example 8

The procedure in this example was performed in the same manner as described in Example 2, except that 2.7 wt % of the glass frit was added, and 0.1 wt % of WO₃ (0.2 μm) was used.

### Example 9

The procedure in this example was performed in the same manner as described in Example 2, except that 2.7 wt % of the glass frit was added, and 0.2 wt % of WO₃ (0.2 μm) was used.

### Example 10

The procedure in this example was performed in the same manner as described in Example 2, except that 2.7 wt % of the glass frit was added, and 0.3 wt % of WO₃ (0.2 μm) was used.

### Example 11

The procedure in this example was performed in the same manner as described in Example 2, except that 2.7 wt % of the glass frit was added, and 0.4 wt % of WO₃ (0.2 μm) was used.

### Example 12

The procedure in this example was performed in the same manner as described in Example 2, except that 2.7 wt % of the glass frit was added, and 0.5 wt % of WO₃ (0.2 μm) was used.

### Example 13

The procedure in this example was performed in the same manner as described in Example 2, except that 2.7 wt % of the glass frit was added, and 0.1 wt % of WO₃ (0.1 μm) and 0.1 wt % of Sb₂O₃ (0.2 μm) were used.

### Example 14

The procedure in this example was performed in the same manner as described in Example 2, except that 2.7 wt % of the glass frit was added, and 0.1 wt % of WO₃ (0.1 μm) and 0.2 wt % of Sb₂O₃ (0.2 μm) were used.

### Example 15

The procedure in this example was performed in the same manner as described in Example 2, except that 2.7 wt % of the glass frit was added, and 0.1 wt % of WO₃ (0.1 μm) and 0.3 wt % of Sb₂O₃ (0.2 μm) were used.

### Example 16

The procedure in this example was performed in the same manner as described in Example 2, except that 2.7 wt % of the glass frit was added, and 0.1 wt % of WO₃ (0.1 μm) and 0.4 wt % of Sb₂O₃ (0.2 μm) were used.

### Example 17

The procedure in this example was performed in the same manner as described in Example 2, except that 2.7 wt % of the glass frit was added, and 0.1 wt % of WO₃ (0.1 μm) and 0.5 wt % of Sb₂O₃ (0.2 μm) were used.

### Example 18

The procedure in this example was performed in the same manner as described in Example 16, except that WO₃ having a particle size of 0.02 μm was used.

### Example 19

The procedure in this example was performed in the same manner as described in Example 16, except that WO₃ having a particle size of 0.05 μm was used.

### Example 20

The procedure in this example was performed in the same manner as described in Example 2, except that 2.7 wt % of the glass frit was added, and 0.1 wt % of NiO (0.1 μm) was used.

### Example 21

The procedure in this example was performed in the same manner as described in Example 2, except that 2.7 wt % of the glass frit was added, and 0.1 wt % of CuO (0.1 μm) was used.

### Example 22

The procedure in this example was performed in the same manner as described in Example 2, except that 2.7 wt % of the glass frit was added, and 0.1 wt % of Bi₂O₃ (0.1 μm) was used.

### Test of Characteristics

Examples 1 to 22 were measured for adhesion, open-circuit voltage, and contact resistance, and the results are shown in Table 1 below. IV characteristics/EL characteristics were measured using a tester by HALM Elektronik. Adhesion characteristics were measured in such a manner that a SnPbAg-coated ribbon was bonded to an electrode, and then a tensile strength meter was used to pull a bonded portion in the 180-degree direction while holding one end of the bonded portion to measure a force (N) required until a front electrode and the ribbon were delaminated. EL line breaks were visually observed. Further, as a parameter for determining whether both adhesion and contact resistance are excellent, a value obtained by calculating the sum (S_{d}) of deviation for a maximum adhesion value (3.2 N) and deviation for a minimum contact resistance value (0.00095 ohm) is shown in Table 1 below.

TABLE 1

| | Glass | WO₃ | WO₃ | Sb₂O₃ | Sb₂O₃ | | | | Adhesion | Voc | FF | Rs | |
|---|---|---|---|---|---|---|---|---|---|---|---|---|---|
| | frit | (0.1 μm) | (0.1 μm) | (0.2 μm) | (0.05 μm) | NiO | CuO | Bi₂O₃ | (N) | (V) | (%) | (ohm) | S_{d} |
| Example1 | 2.5 | — | — | — | — | — | — | — | 1.8 | 0.6301 | 79.71 | 0.00097 | 0.46 |
| Example2 | 2.7 | — | — | — | — | — | — | — | 2 | 0.6301 | 79.72 | 0.00095 | 0.38 |
| Example3 | 2.9 | — | — | — | — | — | — | — | 2.1 | 0.6285 | 79.77 | 0.00098 | 0.38 |
| Example4 | 3.1 | — | — | — | — | — | — | — | 2.3 | 0.628 | 79.78 | 0.00098 | 0.31 |
| Example5 | 2.7 | 0.1 | — | — | — | — | — | — | 2.2 | 0.6301 | 79.71 | 0.00095 | 0.31 |
| Example6 | 2.7 | 0.2 | — | — | — | — | — | — | 2.4 | 0.63 | 79.51 | 0.00103 | 0.33 |
| Example7 | 2.7 | 0.3 | — | — | — | — | — | — | 2.5 | 0.6301 | 79.37 | 0.00127 | 0.56 |
| Example8 | 2.7 | — | — | 0.1 | — | — | — | — | 2.3 | 0.63 | 79.71 | 0.00098 | 0.31 |
| Example9 | 2.7 | — | — | 0.2 | — | — | — | — | 2.6 | 0.6299 | 79.73 | 0.00096 | 0.20 |
| Example10 | 2.7 | — | — | 0.3 | — | — | — | — | 2.7 | 0.6298 | 79.73 | 0.00096 | 0.17 |
| Example11 | 2.7 | — | — | 0.4 | — | — | — | — | 2.9 | 0.63 | 79.75 | 0.00097 | 0.11 |
| Example12 | 2.7 | — | — | 0.5 | — | — | — | — | 2.6 | 0.63 | 79.69 | 0.00101 | 0.25 |
| Example13 | 2.7 | 0.1 | — | 0.1 | — | — | — | — | 2.4 | 0.6298 | 79.71 | 0.00097 | 0.27 |
| Example14 | 2.7 | 0.1 | — | 0.2 | — | — | — | — | 2.5 | 0.6298 | 79.73 | 0.00098 | 0.25 |
| Example15 | 2.7 | 0.1 | — | 0.3 | — | — | — | — | 2.8 | 0.63 | 79.73 | 0.00098 | 0.16 |
| Example16 | 2.7 | 0.1 | — | 0.4 | — | — | — | — | 3.2 | 0.6299 | 79.72 | 0.001 | 0.05 |
| Example17 | 2.7 | 0.1 | — | 0.5 | — | — | — | — | 2.6 | 0.6295 | 79.68 | 0.00105 | 0.29 |
| Example18 | 2.7 | — | 0.1 | 0.4 | — | — | — | — | 2.1 | 0.6295 | 79.65 | 0.00103 | 0.43 |
| Example19 | 2.7 | 0.1 | — | — | 0.4 | — | — | — | 2.3 | 0.6296 | 79.67 | 0.00105 | 0.39 |
| Example20 | 2.7 | — | — | — | — | 0.1 | — | — | 2.4 | 0.63 | 79.41 | 0.00131 | 0.63 |
| Example21 | 2.7 | — | — | — | — | — | 0.1 | — | 2.5 | 0.6299 | 79.35 | 0.00133 | 0.62 |
| Example22 | 2.7 | — | — | — | — | — | — | 0.1 | 2.2 | 0.63 | 79.36 | 0.0013 | 0.68 |

From the above results, it can be seen that as a method of reducing leaching occurring upon ribbon attachment in order to increase adhesion, when Sb₂O₃ and WO₃ were added among metal oxides, adhesion was increased. Further, it can be seen that in Examples 8 to 17 in which 0.2 μm of Sb₂O₃ was added, the sum (S_{d}) of deviation for the maximum adhesion value (3.2 N) and deviation for the minimum contact resistance value (0.00095 ohm) was equal to or less than 0.31, and adhesion was excellent while contact resistance was also excellent. Further, it can be seen that in Examples 9 to 11 and 14 to 16 in which 0.2 μm of Sb₂O₃ was added, the sum (S_{d}) of deviation for the maximum adhesion value (3.2 N) and deviation for the minimum contact resistance value (0.00095 ohm) was equal or less than 0.2, and adhesion was the most excellent while contact resistance was excellent. Further, it can be seen that when the same amount of 2 μm of Sb₂O₃ was added in the range of 0.1 to 0.5%, Examples 13 to 17 in which of 0.1 μm of WO₃ was added had better adhesion and contact resistance than Examples 8 to 12 in which WO₃ was not added.

Further, it can be seen that in Examples 20 to 22 in which NiO, CuO, and Bi₂O₃ were added, adhesion was increased. However, it is seen that when NiO, CuO, and Bi₂O₃ were added, contact resistance, which is a physical property required for an electrode material for a solar cell, was very high, which is disadvantageous in contact resistance characteristics.

Further, referring to Example 4, it can be seen that adhesion was increased with the increase in the amount of the glass frit, but in this case, it can be seen that Voc was decreased due to junction damage.

Further, referring to Example 7, it can be seen that adhesion was increased with the increase in the amount of WO₃, but in this case, it can be seen that there was a tendency for FF to decrease due to poor contact resistance.

Further, referring to Example 17, it can be seen that when the amount of Sb₂O was equal to or greater than a predetermined amount, there was a tendency for adhesion to decrease.

The features, structures, and effects illustrated in individual exemplary embodiments as above can be combined or modified with other exemplary embodiments by those skilled in the art. Therefore, content related to such combinations or modifications should be understood to fall within the scope of the present invention.

### DESCRIPTION OF THE REFERENCE NUMERALS IN THE DRAWINGS

10: p-type silicon semiconductor substrate
20: n-type impurity layer
30: anti-reflection film
40: p+layer (BSF: back surface field)
50: back aluminum electrode
60: back silver electrode
100: front electrode

1. An electroconductive paste for a solar cell electrode, the electroconductive paste comprising:
a metal powder;
a glass frit;
a metal oxide;
an organic binder; and
a solvent,
wherein the metal oxide comprises an oxide of at least any one of metals selected from a group consisting of tungsten (W), antimony (Sb), nickel (Ni), copper (Cu), magnesium (Mg), calcium (Ca), ruthenium (Ru), molybdenum (Mo), and bismuth (Bi).

2. The electroconductive paste of claim 1, wherein the metal oxide comprises an oxide of antimony (Sb).

3. The electroconductive paste of claim 2, wherein with respect to a total weight of the electroconductive paste, an amount of the metal oxide is 0.1 to 0.5 wt %.

4. The electroconductive paste of claim 1, wherein the metal oxide comprises a first metal oxide and a second metal oxide of at least any two of metals selected from a group consisting of tungsten (W), antimony (Sb), nickel (Ni), copper (Cu), magnesium (Mg), calcium (Ca), ruthenium (Ru), molybdenum (Mo), and bismuth (Bi).

5. The electroconductive paste of claim 4, wherein the first metal oxide is an oxide of tungsten (W), and the second metal oxide is an oxide of antimony (Sb).

6. The electroconductive paste of claim 5, wherein a weight ratio of the first metal oxide to the second metal oxide is 1:1 to 5.

7. The electroconductive paste of claim 5, wherein with respect to a total weight of the electroconductive paste, an amount of the first metal oxide is 0.1 to 0.3 wt %, and an amount of the second metal oxide is 0.1 to 0.5 wt %.

8. The electroconductive paste of claim 1, wherein with respect to a total weight of the electroconductive paste, an amount of the glass frit is 2.5 to 3.1 wt %.

9. A solar cell, comprising:
a front electrode on a substrate; and
a back electrode under the substrate,
wherein the front electrode is produced by applying the electroconductive paste of claim 1, followed by drying and firing.
